(19) United States
(12) Patent Application Publication
(10) Pub. No.: US 2024/0321670 A1
(43) Pub. Date: Sep. 26, 2024

(54) Techniques For Transferring Heat From Electronic Devices Using Heatsinks

(71) Applicant: Altera Corporation, San Jose, CA (US)

(72) Inventors: Atul Maheshwari, Portland, OR (US); Mahesh Kumashikar, Bangalore (IN); Md Altaf Hossain, Portland, OR (US); Ankireddy Nalamalpu, Portland, OR (US); Ritochit Chakraborty, Portland, OR (US); Krishna Bharath Kolluru, Portland, OR (US)

(73) Assignee: Altera Corporation, San Jose, CA (US)

(21) Appl. No.: 18/678,439

(22) Filed: May 30, 2024

(51) Int. Cl. H01L 23/367

(52) U.S. Cl. CPC H01L 23/367

(57) ABSTRACT

An electronic device includes a first layer and a thermal heatsink that comprises a conductive region in a second layer of the electronic device. The thermal heatsink further comprises a first via that extends through the first layer. The first via is filled with conductive material that is coupled to the conductive region. The conductive material in the first via is coupled to an external terminal of the electronic device. The electronic device can also include a second via filled with conductive material that is coupled to the conductive region.

### TECHNICAL FIELD

The present disclosure relates to electronic devices and methods, and more particularly, to techniques for transferring heat from electronic devices using heatsinks.

### BACKGROUND

Integrated circuits (ICs) are often housed in integrated circuit (IC) packages. An IC package contains conductors that couple an integrated circuit (IC) to conductive pads exposed on a surface of the IC package. The conductive pads on the surface of the IC package are typically coupled to a circuit board through conductive connections, such as conductive balls.

### BRIEF DESCRIPTION OF DRAWINGS

FIG. 1 is a diagram that depicts a cross sectional view of an example of an integrated circuit (IC) package that includes structural silicon, two integrated circuit (IC) dies, and an interposer having a heatsink.

FIG. 2A is a diagram that depicts a top down view of an example of a conductive region in a conductive layer in an integrated circuit package that forms a part of a thermal heatsink according to techniques disclosed herein.

FIG. 2B is a diagram that depicts a top down view of examples of conductors in two conductive layers in an integrated circuit package that form part of a thermal heatsink according to techniques disclosed herein.

FIG. 3 is a diagram that depicts a cross sectional view of another example of an integrated circuit (IC) package that includes structural silicon, two integrated circuit dies, and an interposer having a heatsink.

FIG. 4 is a diagram that depicts a cross sectional view of yet another example of an integrated circuit (IC) package that includes structural silicon, integrated circuit dies, and an interposer having a heatsink.

FIG. 5 is a diagram of an illustrative example of a configurable integrated circuit (IC).

FIG. 6A illustrates a block diagram of a system that can be used to implement a circuit design to be programmed into a programmable logic device using design software.

FIG. 6B is a diagram that depicts an example of a programmable logic device that includes fabric dies and base dies that are connected to one another via microbumps.

FIG. 7 is a block diagram illustrating a computing system configured to implement one or more aspects of the embodiments described herein.

### DETAILED DESCRIPTION

In some types of field programmable gate arrays (FPGAs), the high bandwidth interface (HBI) process flow increases thermal resistance and results in higher local temperatures. The higher temperatures create a significant challenge for an FPGA, particularly if the serializer/deserializer circuitry and/or the input/output circuitry have much higher power and thermal density compared to the fabric region of the FPGA.

According to some examples disclosed herein, an integrated circuit package includes a thermal heatsink that transfers heat away from hotspots in the integrated circuit package. The thermal heatsink is located within an integrated circuit die (e.g., a field programmable gate array, microprocessor, etc.), a backside power delivery device, and/or within an interposer in the integrated circuit package. The thermal heatsink can, for example, include one or more conductive regions coupled to one or more conductive vias in one or both of the integrated circuit die and/or the interposer in the integrated circuit package. The conductive regions and conductive vias are not coupled to a source of electrical current or to a voltage source. Heat is transferred from hotspots in the integrated circuit die (e.g., serializer/deserializer circuitry and/or input/output circuitry) to the interposer through the thermal heatsink. Heat is then transferred from the interposer to the integrated circuit package substrate. The thermal heatsink can improve thermal conductivity in the integrated circuit die and in the interposer. The thermal heatsink can, as examples, reduce the temperatures of hotspots in the integrated circuit die by 2-3° Celsius. The thermal heatsink can be used in 2.5 dimensional and 3 dimensional integrated circuit packages.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

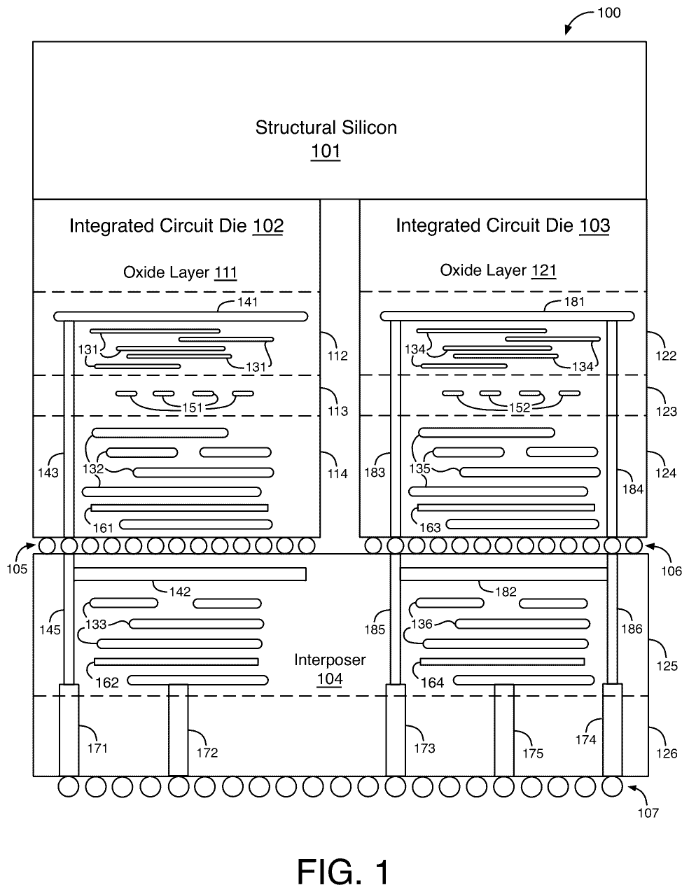

Figure (FIG. 1 is a diagram that depicts a cross sectional view of an example of an integrated circuit (IC) package 100 that includes structural silicon 101, two integrated circuit (IC) dies 102-103, and an interposer 104. Each of the integrated circuit (IC) dies 102-103 (also referred to as integrated circuits) can be any type of IC, such as a configurable logic IC (e.g., a field programmable gate array), a microprocessor, a graphics processing unit (GPU) IC, a transceiver IC, a memory IC, an application specific integrated circuit (ASIC), or a structured ASIC. Structural silicon 101 holds together IC dies 102-103. Interposer 104 can be an active or passive interposer. As used herein, electronic devices include interposers and integrated circuit dies.

The integrated circuit (IC) die 102 includes an oxide layer 111, conductive layers 112, active (semiconductor) layers 113, and conductive layers 114. The integrated circuit (IC) die 103 includes an oxide layer 121, conductive layers 122, active (semiconductor) layers 123, and conductive layers 124. The interposer 104 includes regions 125-126. Any of the conductors, conductive regions or material, and/or conductive layers disclosed herein can include metal and/or metallic alloys.

The conductive layers 112 in IC die 102 include conductors, such as conductors 131. Conductors are also referred to as conductive regions herein. The active layers 113 in IC die 102 include transistors, such as transistors 151. The conductive layers 114 in IC die 102 include conductors, such as conductors 132, and capacitors, such as capacitor 161. Some of the conductors (e.g., conductors 131) in conductive layers 112 can, for example, be used to transmit signals between the transistors in active layers 113, such as transistors 151. Some of the conductors (e.g., conductors 132) in conductive layers 114 can be used to transmit power supply voltages and ground voltages to the transistors (e.g., transistors 151) in active layers 113.

The conductive layers 122 in IC die 103 include conductors, such as conductors 134. The active layers 123 in IC die 103 include transistors, such as transistors 152. The conductive layers 124 in IC die 103 include conductors, such as conductors 135, and capacitors, such as capacitor 163. Some of the conductors (e.g., conductors 134) in conductive layers 122 can, for example, be used to transmit signals between the transistors in active layers 123, such as transistors 152. Some of the conductors (e.g., conductors 135) in conductive layers 124 can be used to transmit power supply voltages and ground voltages to the transistors (e.g., transistors 152) in active layers 123.

Region 125 of interposer 104 includes layers of conductors, including conductors 133, conductors 136, one or more conductors 142, and one or more conductors 182. Region 125 also includes capacitors, such as capacitors 162 and 164. Region 126 of interposer 104 includes vias filled with conductive material, including vias 171-175. The top portions of vias 171-175 extend into region 125. Regions 125 and 126 are delineated by a dotted line in FIG. 1. Vias 172 and 175 are coupled to conductors in region 125 of the interposer 104.

The IC package 100 also includes conductive connections (e.g., microbumps) 105, 106, and 107. Conductive connections 105 couple IC die 102 to interposer 104, and conductive connections 106 couple IC die 103 to interposer 104. Conductive connections 107 can couple the interposer 104 to a package substrate (not shown) of the IC package 100.

Each of the integrated circuit dies 102-103 and the interposer 104 has at least one thermal heatsink. IC die 102 has a thermal heatsink that is L-shaped in the cross sectional view of FIG. 1. The L-shaped thermal heatsink in IC die 102 includes one or more conductors 141 in one or more of the conductive layers 112 and a via 143 filled with conductive material. The one or more conductors 141 are coupled to the conductive material in the via 143. Via 143 extends through layers 112-114.

The interposer 104 has a first thermal heatsink that is L-shaped in the cross sectional view of FIG. 1. The L-shaped thermal heatsink in interposer 104 includes one or more conductors 142 in one or more conductive layers in region 125, a via 145 filled with conductive material in region 125, and a via 171 filled with conductive material in region 126. The one or more conductors 142 are coupled to the conductive material in via 145. The conductive material in via 145 is coupled to the conductive material in via 171.

The L-shaped thermal heatsink that includes one or more conductors 142 and via 145 in interposer 104 is coupled to the L-shaped thermal heatsink that includes one or more conductors 141 and via 143 in IC die 102 through one of the conductive connections 105, through a conductive pad of interposer 104 connected to the one of conductive connections 105, and through a conductive pad of integrated circuit die 102 connected to the one of the conductive connections 105. The conductive pads are external terminals of the electronic devices. The conductors and conductive vias in the L-shaped thermal heatsinks are decoupled from any source of electrical current or voltage. As a result, the voltage of the thermal vias floats.

The L-shaped thermal heatsink in IC die 102 transfers heat away from hotspots in IC die 102. Hotspots in IC die 102 can include, for example, serializer/deserializer circuitry and/or input/output (IO) circuitry in layers 113 of the IC die 102. The L-shaped thermal heatsink in IC die 102 transfers heat away from the hotspots in IC die 102 to the L-shaped thermal heatsink in the interposer 104 through one of the conductive connections 105 and the pads. The L-shaped thermal heatsink in interposer 104 then transfers the heat from interposer 104 to the integrated circuit package 100 (e.g., a package substrate) through one of the conductive connections 107. The L-shaped thermal heatsinks can improve thermal conductivity in the IC die 102 and in the interposer 104.

IC die 103 has a thermal heatsink that is shaped as an upside down U in the cross sectional view of FIG. 1. The U-shaped thermal heatsink in IC die 103 includes one or more conductors 181 in one or more of the conductive layers 122 and two vias 183-184 filled with conductive material. The one or more conductors 181 are coupled to the conductive material in each of the vias 183-184. Vias 183-184 extend through layers 122-124.

The interposer 104 also has a second thermal heatsink that is shaped as an upside down U in the cross sectional view of FIG. 1. The U-shaped thermal heatsink in interposer 104 includes one or more conductors 182 in one or more conductive layers in region 125, vias 185 and 186 filled with conductive material in region 125, and vias 173 and 174 filled with conductive material in region 126. The one or more conductors 182 are coupled to the conductive material in each of the vias 185-186. The conductive material in vias 185-186 are coupled to the conductive material in vias 173-174, respectively.

The U-shaped thermal heatsink that includes the one or more conductors 182 and vias 185-186 and 173-174 in interposer 104 is coupled to the U-shaped thermal heatsink that includes the one or more conductors 181 and vias 183-184 in IC die 103 through two of the conductive connections 106, through 2 conductive pads of interposer 104 that are coupled to the two conductive connections 106, and through 2 conductive pads of integrated circuit die 103 that are coupled to the 2 conductive connections 106. The conductors and conductive vias in the U-shaped thermal heatsinks are decoupled from any source of electrical current or voltage. As a result, the voltage of the thermal vias floats.

The U-shaped thermal heatsink in IC die 103 transfers heat away from hotspots in IC die 103. The hotspots in IC die 103 can include, for example, serializer/deserializer circuitry and/or input/output (IO) circuitry in layers 123 of the IC die 103. The U-shaped thermal heatsink in IC die 103 transfers heat from the hotspots in IC die 103 to the U-shaped thermal heatsink in the interposer 104 through 2 of the conductive connections 106. The U-shaped thermal heatsink in the interposer 104 then transfers the heat from the interposer 104 to the integrated circuit package 100 (e.g., the package substrate) through 2 of the conductive connections 107. The U-shaped thermal heatsinks can improve thermal conductivity in the IC die 103 and in the interposer 104.

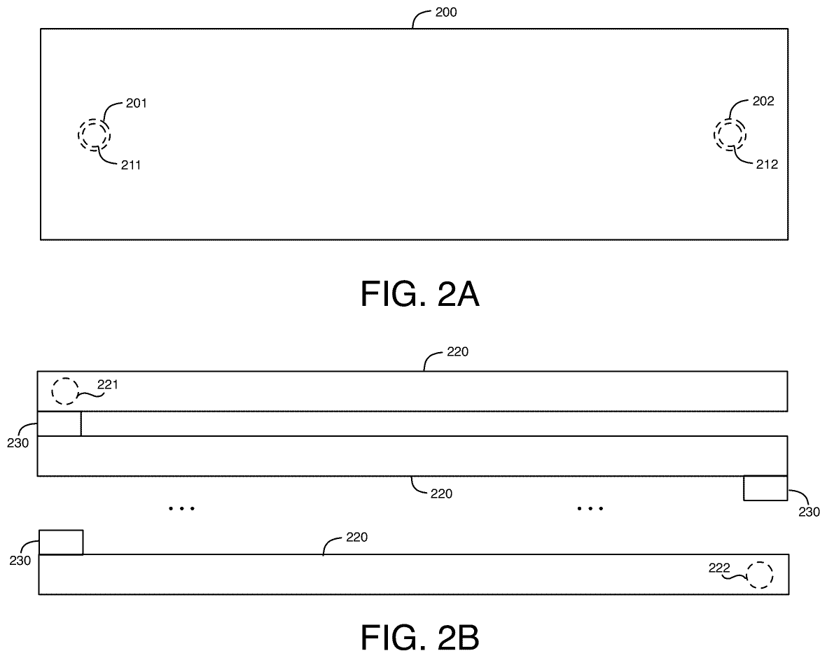

FIG. 2A is a diagram that depicts a top down view of an example of a conductor 200 in a conductive layer in an integrated circuit package that forms a part of a thermal heatsink according to techniques disclosed herein. Conductor 200 is a rectangular shaped conductive region in a conductive layer that forms part of a thermal heatsink. According to various examples, conductors used in heatsinks as disclosed herein can be any shape from a top down view. Conductor 200 can be in an IC die or interposer. Conductor 200 can extend across a portion of, or all of, the width and/or length of an IC die or interposer in the IC package.

Conductor 200 can be, as examples, one of conductors 141 in IC die 102, one of conductors 142 in interposer 104, one of conductors 181 in IC die 103, and/or one of conductors 182 in interposer 104 in the thermal heatsinks of FIG. 1. Conductor 200 is coupled to conductive material in one or both of vias 201-202. Vias 201-202 can be, as examples, vias 183-184 or vias 185-186 in the U-shaped thermal heatsink of IC die 103 or interposer 104, respectively. Either of the vias 201 or 202 can be, as examples, via 143 or via 145 in the L-shaped thermal heatsink of IC die 102 or interposer 104, respectively. The conductive material in vias 201 and 202 is coupled to conductive pads 211 and 212, respectively, of the electronic device (e.g., the IC die or interposer). The conductive pads 211-212 are external terminals of the electronic device that are coupled to conductive connections, such as conductive connections 105 or 106. According to other examples, a thermal heatsink can include conductive regions in multiple conductive layers of the electronic device that are coupled together. The conductive regions can overlap in a top down view.

FIG. 2B is a diagram that depicts a top down view of examples of conductors 220 and 230 in two conductive layers in an integrated circuit package that form part of a thermal heatsink according to techniques disclosed herein. The thermal heatsink includes conductors 220 and 230 that are coupled together in an alternating back and forth pattern in the example shown in FIG. 2B. Conductors 220 are in a first conductive layer, and conductors 230 are in a second conductive layer. Each of the conductors 230 couples together two of the conductors 220. Conductors 220 and 230 can be in an IC die or interposer. Conductors 220 and 230 extend across a portion of, or all of, the width and/or length of an IC die or interposer in the IC package.

Although 3 conductors 220 and 3 conductors 230 are shown in FIG. 2B as an example, thermal heatsinks as disclosed herein can include any number of the conductors 220 and 230. Conductors 220 and 230 can be, as examples, conductors 141 in IC die 102, conductors 142 in interposer 104, conductors 181 in IC die 103, and/or conductors 182 in interposer 104 in the thermal heatsinks of FIG. 1.

A first one of the conductors 220 is coupled to conductive material in via 221, and a second one of the conductors 220 is coupled to conductive material in via 222. Vias 221-222 can be, as examples, vias 183-184 or vias 185-186 in the U-shaped thermal heatsink of IC die 103 or interposer 104, respectively. Either of the vias 221 or 222 can be, as examples, via 143 or via 145 in the L-shaped thermal heatsink of IC die 102 or interposer 104, respectively.

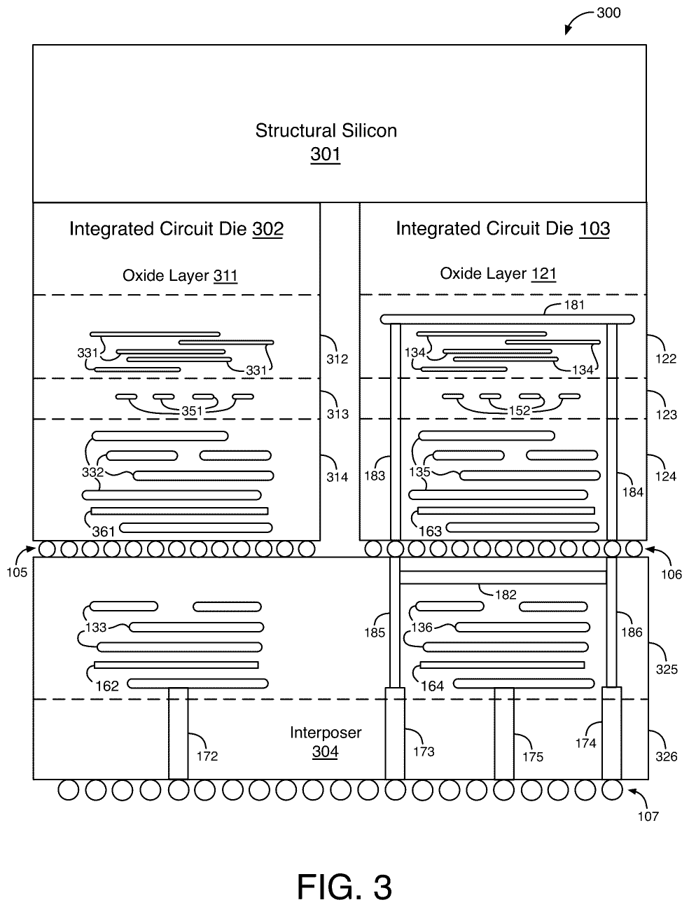

FIG. 3 is a diagram that depicts a cross sectional view of an example of an integrated circuit (IC) package 300 that includes structural silicon 301, two integrated circuit dies 302 and 103, and an interposer 304. Each of the integrated circuit (IC) dies 302 and 103 can be any type of IC, such as a configurable logic IC (e.g., a field programmable gate array), a microprocessor, a graphics processing unit, a transceiver IC, a memory IC, an application specific integrated circuit (ASIC), or a structured ASIC. IC die 103 is described in detail herein with respect to FIG. 1.

The integrated circuit (IC) die 302 includes an oxide layer 311, conductive layers 312, active layers 313, and conductive layers 314. The conductive layers 312 in IC die 302 include conductors, such as conductors 331. The active layers 313 in IC die 302 include transistors, such as transistors 351. The conductive layers 314 in IC die 302 include conductors, such as conductors 332, and capacitors, such as capacitor 361. In the example of FIG. 3, IC die 302 does not include an internal thermal heatsink, and IC die 103 includes the U-shaped thermal heatsink described herein with respect to FIG. 1.

Interposer 304 includes regions 325-326. Regions 325 and 326 are delineated by a dotted line in FIG. 3. Region 325 of interposer 304 includes layers of conductors, including conductors 133, conductors 136, and the one or more conductors 182. Region 325 also includes capacitors, such as capacitors 162 and 164. Region 326 of interposer 304 includes vias filled with conductive material, including vias 172-175. The top portions of vias 172-175 extend into region 325. Interposer 304 includes the U-shaped thermal heatsink described above with respect to FIG. 1 that includes conductors 182, vias 185-186, and vias 173-174. Interposer 304 does not include a thermal heatsink coupled to IC die 302.

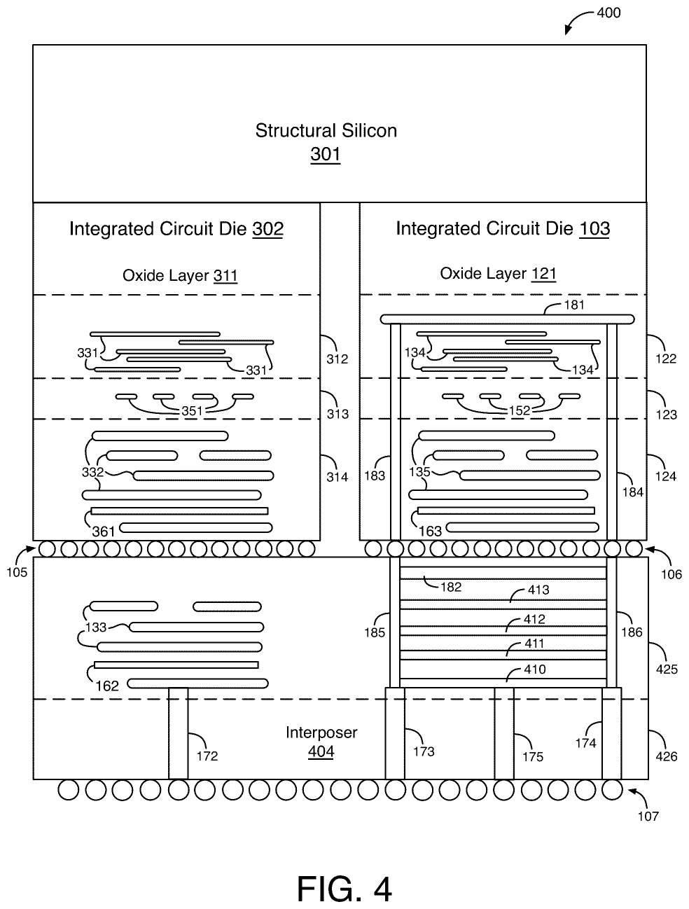

FIG. 4 is a diagram that depicts a cross sectional view of an example of an integrated circuit (IC) package 400 that includes structural silicon 301, integrated circuit dies 302 and 103, and an interposer 404. Structural silicon 301 and IC dies 103 and 302 are described in detail herein with respect to FIGS. 1 and 3.

Interposer 404 includes regions 425-426 that are delineated by a dotted line in FIG. 4. Region 425 of interposer 404 includes layers of conductors, including conductors 133, the one or more conductors 182, conductors 410-413, and vias 185-186. Region 425 can also include capacitors, such as capacitor 162. Region 426 of interposer 404 includes vias filled with conductive material, including vias 172-175. The top portions of vias 172-175 extend into region 425. Interposer 404 does not include a thermal heatsink coupled to IC die 302.

Interposer 404 includes a thermal heatsink that is coupled to the U-shaped thermal heatsink in IC die 103 through 2 of conductive connections 106. The thermal heatsink in interposer 404 includes the one or more conductors 182, vias 185-186, conductors 410-413, and vias 173-175. The one or more conductors 182 in the thermal heatsink are coupled to the conductive material in each of vias 185-186. The conductors 410, 411, 412, and 413 in the thermal heatsink are also coupled to the conductive material in each of vias 185-186. The one or more conductors 410 are coupled to the conductive material in each of vias 173, 174, and 175. The conductive material in vias 185 and 186 is coupled to the conductive material in vias 173 and 174, respectively. Thus, the thermal heatsink in interposer 404 includes additional conductors 410-413 that are coupled to the conductive material in vias 185, 186, and 173-175. The thermal heatsink is decoupled from any voltage or current source.

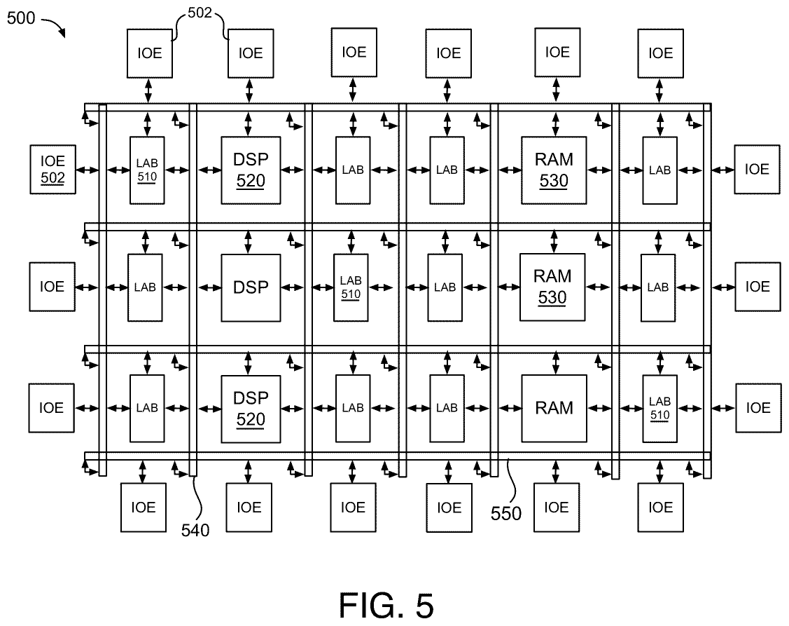

FIG. 5 is a diagram of an illustrative example of a configurable integrated circuit (IC) 500. Configurable IC 500 is an example of an IC that can be in the IC packages disclosed herein with respect to FIGS. 1, 3, and/or 4, such as IC dies 102-103 or 302. As shown in FIG. 5, the configurable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals.

In addition, configurable logic IC 500 can have input/output elements (IOEs) 502 for driving signals off of configurable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the configurable logic IC 500 can have input/output elements 502 arranged in different ways. For example, input/output elements 502 can form one or more columns, rows, or islands of input/output elements that may be located anywhere on the configurable logic IC 500.

The configurable logic IC 500 can also include programmable interconnect circuitry in the form of vertical routing channels 540 (i.e., interconnects formed along a vertical axis of configurable logic IC 500) and horizontal routing channels 550 (i.e., interconnects formed along a horizontal axis of configurable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Configurable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, configurable logic IC 500 can include configuration memory that is organized in sectors, whereby a sector can include the configuration RAM bits that specify the functions and/or interconnections of the subcomponents and wires in or crossing that sector. Each sector can include separate data and address registers.

The configurable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

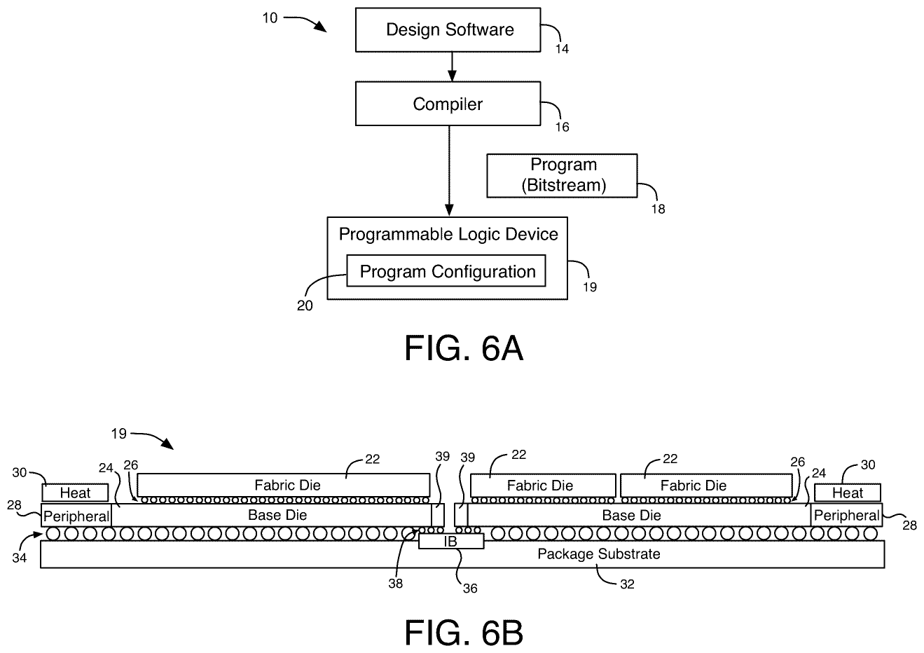

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

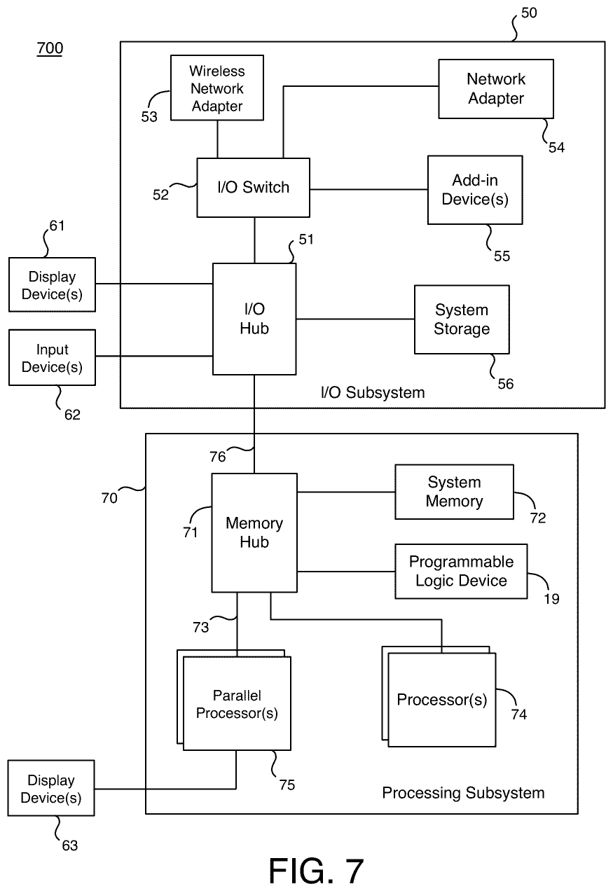

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.
Additional examples are now described. Example 1 is an electronic device comprising: a first layer; and a thermal heatsink that comprises a first conductive region in a second layer of the electronic device, wherein the thermal heatsink further comprises a first via that extends through the first layer, wherein the first via is filled with first conductive material coupled to the first conductive region, wherein the first conductive material in the first via is coupled to a first external terminal of the electronic device, and wherein the thermal heatsink is decoupled from any voltage source.
In Example 2, the electronic device of Example 1 can optionally include, wherein the thermal heatsink further comprises a second conductive region in a third layer of the electronic device, and wherein the second conductive region is coupled to the first conductive region.
In Example 3, the electronic device of any one of Examples 1-2 can optionally include, wherein the first via extends through third layers comprising transistors.
In Example 4, the electronic device of any one of Examples 1-3 can optionally include, wherein the thermal heatsink further comprises a second via that extends through the first layer, wherein the second via is filled with second conductive material and is coupled to the first conductive region, and wherein the second conductive material in the second via is coupled to a second external terminal of the electronic device.
In Example 5, the electronic device of any one of Examples 1˜4 can optionally include, wherein the thermal heatsink has an L-shape in a cross sectional view of the electronic device.
In Example 6, the electronic device of any one of Examples 1˜4 can optionally include, wherein the thermal heatsink has a U-shape in a cross sectional view of the electronic device.
In Example 7, the electronic device of any one of Examples 1-6 can optionally include, wherein the thermal heatsink further comprises a second conductive region in the second layer of the electronic device, and wherein the second conductive region is coupled to the first conductive region.
In Example 8, the electronic device of any one of Examples 1-7 can optionally include, wherein the electronic device is an integrated circuit.
In Example 9, the electronic device of any one of Examples 1-7 can optionally include, wherein the electronic device is an interposer.

Example 10 is a method for transferring heat from an electronic device using a heatsink, the method comprising: transferring heat from a heat source in the electronic device through a first conductor in a first layer of the electronic device; and transferring at least a first portion of the heat from the first conductor through first conductive material in a first via that extends through a second layer of the electronic device to a first external pad of the electronic device, wherein the heatsink comprises the first conductor and the first conductive material in the first via, and wherein the heatsink is decoupled from any source of electrical current.

In Example 11, the method of Example 10 further comprises: transferring a second portion of the heat from the first conductor through second conductive material in a second via that extends through the second layer to a second external pad of the electronic device, wherein the heatsink further comprises the second conductive material in the second via.

In Example 12, the method of any one of Examples 10-11 further comprises: transferring the heat from the first conductor through a second conductor in a third layer of the electronic device to the first conductive material in the first via, wherein the heatsink further comprises the second conductor.

In Example 13, the method of any one of Examples 10-12 can optionally include, wherein the first via extends through active layers of the electronic device that comprise transistors.

In Example 14, the method of any one of Examples 10-13 can optionally include, wherein the heatsink is one of an L-shape or a U-shape from a cross sectional view of the electronic device.

In Example 15, the method of any one of Examples 10-14 can optionally include, wherein the electronic device is an integrated circuit die.

In Example 16, the method of any one of Examples 10-15 can optionally include, wherein the electronic device is an interposer.

Example 17 is an integrated circuit package comprising: an integrated circuit die comprising a first heatsink, wherein the first heat sink comprises a first conductive region in a first layer of the integrated circuit die, wherein the first heatsink further comprises a first via that extends through a second layer of the integrated circuit die, and wherein the first via is filled with first conductive material that is coupled to the first conductive region; and an interposer coupled to the integrated circuit die, wherein the interposer comprises a second heatsink, wherein the second heatsink comprises a second conductive region in a third layer of the interposer, wherein the second heatsink further comprises a second via filled with second conductive material that is coupled to the second conductive region, and wherein the second conductive material in the second via is coupled to the first conductive material in the first via.
In Example 18, the integrated circuit package of Example 17 can optionally include, wherein the second via extends through a fourth layer of the interposer, and wherein the first conductive material in the first via and the second conductive material in the second via are coupled together through a conductive connection between the interposer and the integrated circuit die.
In Example 19, the integrated circuit package of any one of Examples 17-18 can optionally include, wherein the first heatsink further comprises third conductive material in a third via that is coupled to the first conductive region, and wherein the second heatsink further comprises fourth conductive material in a fourth via that is coupled to the second conductive region and to the third conductive material in the third via.
In Example 20, the integrated circuit package of any one of Examples 17-19 can optionally include, wherein the first heatsink and the second heatsink are decoupled from any voltage source.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An electronic device comprising:
a first layer; and
a thermal heatsink that comprises a first conductive region in a second layer of the electronic device, wherein the thermal heatsink further comprises a first via that extends through the first layer, wherein the first via is filled with first conductive material coupled to the first conductive region, wherein the first conductive material in the first via is coupled to a first external terminal of the electronic device, and wherein the thermal heatsink is decoupled from any voltage source.

2. The electronic device of claim 1, wherein the thermal heatsink further comprises a second conductive region in a third layer of the electronic device, and wherein the second conductive region is coupled to the first conductive region.

3. The electronic device of claim 1, wherein the first via extends through third layers comprising transistors.

4. The electronic device of claim 1, wherein the thermal heatsink further comprises a second via that extends through the first layer, wherein the second via is filled with second conductive material and is coupled to the first conductive region, and wherein the second conductive material in the second via is coupled to a second external terminal of the electronic device.

5. The electronic device of claim 1, wherein the thermal heatsink has an L-shape in a cross sectional view of the electronic device.

6. The electronic device of claim 1, wherein the thermal heatsink has a U-shape in a cross sectional view of the electronic device.

7. The electronic device of claim 1, wherein the thermal heatsink further comprises a second conductive region in the second layer of the electronic device, and wherein the second conductive region is coupled to the first conductive region.

8. The electronic device of claim 1, wherein the electronic device is an integrated circuit.

9. The electronic device of claim 1, wherein the electronic device is an interposer.

10. A method for transferring heat from an electronic device using a heatsink, the method comprising:
transferring heat from a heat source in the electronic device through a first conductor in a first layer of the electronic device; and
transferring at least a first portion of the heat from the first conductor through first conductive material in a first via that extends through a second layer of the electronic device to a first external pad of the electronic device, wherein the heatsink comprises the first conductor and the first conductive material in the first via, and wherein the heatsink is decoupled from any source of electrical current.

11. The method of claim 10 further comprising:
transferring a second portion of the heat from the first conductor through second conductive material in a second via that extends through the second layer to a second external pad of the electronic device, wherein the heatsink further comprises the second conductive material in the second via.

12. The method of claim 10 further comprising:
transferring the first portion of the heat from the first conductor through a second conductor in a third layer of the electronic device to the first conductive material in the first via, wherein the heatsink further comprises the second conductor.

13. The method of claim 10, wherein the first via extends through active layers of the electronic device that comprise transistors.

14. The method of claim 10, wherein the heatsink is one of an L-shape or a U-shape from a cross sectional view of the electronic device.

15. The method of claim 10, wherein the electronic device is an integrated circuit die.

16. The method of claim 10, wherein the electronic device is an interposer.

17. An integrated circuit package comprising:
an integrated circuit die comprising a first heatsink, wherein the first heatsink comprises a first conductive region in a first layer of the integrated circuit die, wherein the first heatsink further comprises a first via that extends through a second layer of the integrated circuit die, and wherein the first via is filled with first conductive material that is coupled to the first conductive region; and
an interposer coupled to the integrated circuit die, wherein the interposer comprises a second heatsink, wherein the second heatsink comprises a second conductive region in a third layer of the interposer, wherein the second heatsink further comprises a second via filled with second conductive material that is coupled to the second conductive region, and wherein the second conductive material in the second via is coupled to the first conductive material in the first via.

18. The integrated circuit package of claim 17, wherein the second via extends through a fourth layer of the interposer, and wherein the first conductive material in the first via and the second conductive material in the second via are coupled together through a conductive connection between the interposer and the integrated circuit die.

19. The integrated circuit package of claim 17, wherein the first heatsink further comprises third conductive material in a third via that is coupled to the first conductive region, and wherein the second heatsink further comprises fourth conductive material in a fourth via that is coupled to the second conductive region and to the third conductive material in the third via.

20. The integrated circuit package of claim 17, wherein the first heatsink and the second heatsink are decoupled from any voltage source.
